(19) United States
(12) Patent Application Publication
(10) Pub. No.: US 2006/0205122 A1
(43) Pub. Date: Sep. 14, 2006

(54) Method for fabricating a field stop zone

(75) Inventors: Hans-Joachim Schulze, Ottobrunn (DE); Anton Mauder, Kolbermoor (DE); Carsten Schaffer, Sattendorf (AT)

Correspondence Address: Maginot, Moore & Beck;Chase Tower, Suite 3250, 111 Monument Circle, Indianapolis, IN, 46204, US

(73) Assignee: Infineon Technologies Austria AG, Villach (AT)

(21) Appl. No.: 11/357,904

(22) Filed: Feb. 17, 2006

(30) Foreign Application Priority Data
Feb. 18, 2005 (DE) 10 2005 007 599.1

(51) Int. Cl. H01L 21/332

(52) U.S. Cl. 438/133

(57) ABSTRACT

In a method for fabricating a field stop zone in a semiconductor body of a semiconductor component. According to the method, the semiconductor body is irradiated with protons, and the irradiated semiconductor body is subjected to a heat treatment process. Prior to the irradiation process, the semiconductor body is subjected to an RTA process in a nitriding atmosphere.

### BACKGROUND

The invention relates to a method for fabricating a field stop zone in a semiconductor body of a semiconductor component.

Semiconductor components with a field stop zone are known. A detailed description of the technical principles of such semiconductor components may be found for example in the patent specification U.S. Pat. No. 5,668,385. A brief summary of the functioning of a semiconductor component with a field stop zone is given below.

Field stop zones are used for example in semiconductor components which, in a vertical pnp structure with a blocking pn junction—situated at the front side—in the n-type region, have such a low doping that the electric field or the space charge zone would extend as far as a rear side p-type region in the off-state case. Such a “punch-through” of the electric field or the space charge zone has the effect of reducing a breakdown voltage of the semiconductor component. Through the use of a field stop zone, an additional, somewhat more highly doped n-type region is incorporated between the lightly doped n-type region and the rear side p-type region and completely reduces the electric field. The punch-through effect can thus be reliably avoided. Semiconductor components with a field stop zone are referred to as field stop components and may be for example IGBTs (Insulated Gate Bipolar Transistor), MCTs (MOS Controlled Thyristor), GTOs (Gate Turn-Off Thyristor), ESTs (Emitter Switched Thyristor), thyristors or bipolar transistors. Diodes, too, can be designed in this way.

The method for fabricating the field stop zone is independent of the concrete configuration of the front side of the semiconductor component, that is to say that the front side structure may be configured in diverse ways (e.g. have planar MOS cells, continuous or patterned emitters, etc.).

If a field stop zone is not intended to be used, then the lightly doped n-type region may alternatively be made so thick that the electric field or the space charge zone still ends “in good time” before the p-type emitter within the lightly doped n-type region even when a high voltage is present. What is disadvantageous in this case is that a distinctly higher component thickness is required in comparison with semiconductor components with a field stop layer for the same “dielectric strength”, whereby high on-state and/or switching losses occur.

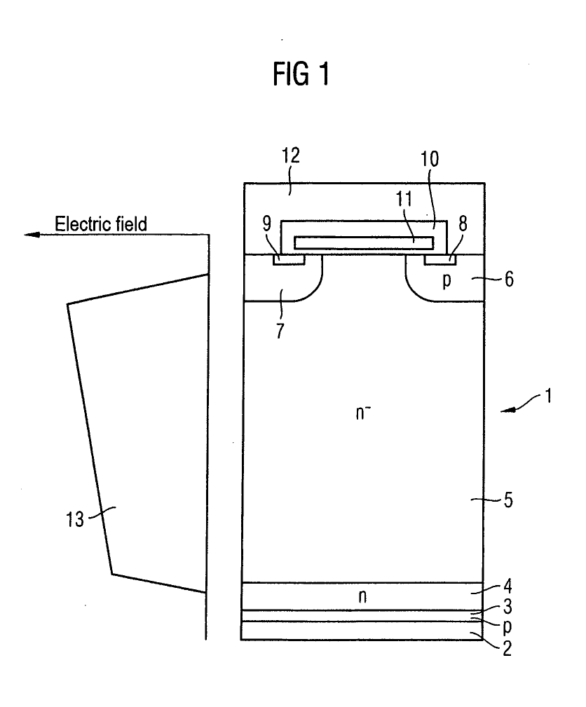

FIG. 1 shows an IGBT semiconductor component 1 with a field stop layer, which is constructed as follows: A p-type emitter layer 3 is arranged in a manner adjoining a rear side metal layer 2, an n-type field stop layer 4 being provided, in turn, on said emitter layer. An n-type base region 5 is provided on the n-type field stop layer 4, the doping intensity of said base region being low compared with that of the n-type field stop layer 4. A first and second p-type body region 6, 7 are incorporated into the top side of the n-type base region or n-type base layer 5. A first n-type source region 8 is situated in the first p-type body region 6; analogously to this, a second n-type source region 9 is provided in the second p-type body region 7. The first p-type body region 6 is separated from the second p-type body region 7 by the n-type base region 5. Furthermore, an insulator layer (oxide layer) 10 which covers the top side of the n-type base region 5 and also parts of the first and second p-type body regions 6, 7 and of the first and second n-type source regions 8, 9. A gate 11 is provided within the oxide layer 10. Surface parts of the first and second p-type body regions 6, 7 and of the first and second n-type source regions 8, 9 which are not covered by the oxide layer 10 are covered by a front side metal layer 12 that also covers the oxide layer 10.

In the off-state case, a space charge zone which proceeds from the first and second p-type body regions 6, 7 and propagates in the n-type base region 5 is stopped by the n-type field stop layer 4, thus resulting in the field distribution identified by reference symbol 13.

The field stop zone should be configured, particularly within IGBT semiconductor components, in such a way that, on the one hand, a sufficient blocking capability of the semiconductor component is guaranteed, but on the other hand satisfactory dynamic properties (for example a sufficiently soft turn-off behavior or a high short-circuit loading capacity) are also made possible. It would furthermore be desirable to fabricate the field stop zone at temperatures of below 500° C. in order that it can also be fabricated in a relatively late process stage (largely finished processed silicon wafer) without detrimentally affecting previously produced structures. If this is possible, relatively thin silicon wafers (substrates) can be used and the on-state losses of the semiconductor component can thus be kept low. This advantage makes a significant difference particularly when IGBTs or diodes having reverse voltages of up to 1800 V are intended to be fabricated, which require particularly small final thicknesses of the substrates.

Experiments have shown that the simultaneous realization of a soft turn-off behavior and a sufficient short-circuit capability necessitates a field stop zone extending deep into the semiconductor body of the semiconductor component (“deep reaching doping profile”) with a small doping gradient. If such deep reaching field stop zone doping profiles are to be fabricated by means of a diffusion method, however, temperatures of above 500° C. are necessary. By way of example, a temperature of above 1100° C. is required in the case of a phosphorus diffusion, and a temperature of above 800° C. is required in the case of a selenium diffusion, in order to produce a sufficiently deep field stop zone doping profile. This has the disadvantage, however, as described above, that it is not possible to fabricate the field stop zone in a relatively late process stage since previously produced structures would be detrimentally affected.

In order to avoid this disadvantage, it is known e.g. from U.S. Pat. No. 6,482,681 B1 to fabricate the field stop zone by means of one or more proton irradiations. Proton irradiations bring about the production of donors in the so-called “end of range” region of the semiconductor body and also to a small extent in the irradiated region, in which case all the more donors are produced, the higher the proton irradiation dose. What is disadvantageous about the use of a proton irradiation is the high outlay that arises in the case of a plurality of irradiation steps having different energies for the production of the deep reaching doping profile. What is furthermore disadvantageous is that when a plurality of proton irradiations having different energies are used, the resulting field stop zone always has a doping profile with a certain “ripple”.

One advantage of the invention disclosed herein is that of specifying a method for fabricating a deep reaching field stop zone within a semiconductor body of a semiconductor component which enables the fabrication of the field stop zone at temperatures of below 500° C. and requires a comparatively low outlay.

### DESCRIPTION AND SUMMARY

A method according to the invention for fabricating a field stop zone in a semiconductor body of a semiconductor component has the following steps: Firstly, the semiconductor body is irradiated with protons. Afterward, the irradiated semiconductor body is subjected to a heat treatment process. Prior to the irradiation process, the semiconductor body is subjected to an RTA (rapid thermal annealing) process in a nitriding atmosphere.

“Nitriding atmosphere” means that the atmosphere in an RTA chamber in which the RTA process is performed should essentially comprise nitrogen.

In one preferred embodiment, the temperature of the RTA process lies in a range of between 1000° C. and 1200° C.

The RTA step has to be effected prior to the deposition of metal and/or passivation layers, and, in the case of very thin (substrate) wafers (semiconductor bodies), expediently prior to the actual thinning process.

The duration of the RTA process may lie in a range extending from a plurality of seconds through to a plurality of hours.

In one preferred embodiment, the doses of the protons during the irradiation process are a plurality of 10¹³ to a plurality of 10¹⁴ protons/cm².

In one preferred embodiment, the temperature of the heat treatment process is 350° C. to 450° C.

The duration of the heat treatment process should be 1 to 4 hours.

The invention can be applied to an arbitrary semiconductor component with a field stop zone, for example an IGBT or a diode. However, other semiconductor components such as, for example, MCTs, GTOs, ESTs or thyristors or bipolar transistors are also conceivable.

The irradiation is preferably effected through the main surface of the semiconductor body (front side or rear side) which lies closer to the field stop zone. This is generally the rear side of the semiconductor body.

Accordingly, the invention involves producing a field stop zone with a relatively high doping concentration closely beneath the wafer surface (“wafer surface”=“substrate surface”) and a doping profile extending into the depth with a shallow gradient by means of—as known e.g. from U.S. Pat. No. 6,482,681 B1—effecting a proton irradiation into the wafer side (substrate side) in which the field stop zone is intended to be produced. However, since such an irradiation leads to a Gaussian doping distribution within the field stop zone to be produced and thus to a relatively steep gradient of the doping profile with respect to the wafer depth, according to the invention a “rapid thermal annealing” (RTA) whose step is carried out in a nitriding atmosphere before the proton irradiation is carried out.

This nitriding RTA step has the effect that vacancies indiffuse into the silicon wafer, the penetration depth and the concentration of the vacancies being defined by the maximum temperature and the time duration of the RTA step. These additional vacancies that have indiffused into the depth bring about, in combination with the hydrogen atoms which indiffuse into the depth of the wafer during a heat treatment subsequent to the proton irradiation, a production of additional donors in the depth of the wafer, the concentration profile of this shallow doping profile tail primarily following the vacancy profile defined by means of the nitriding RTA step.

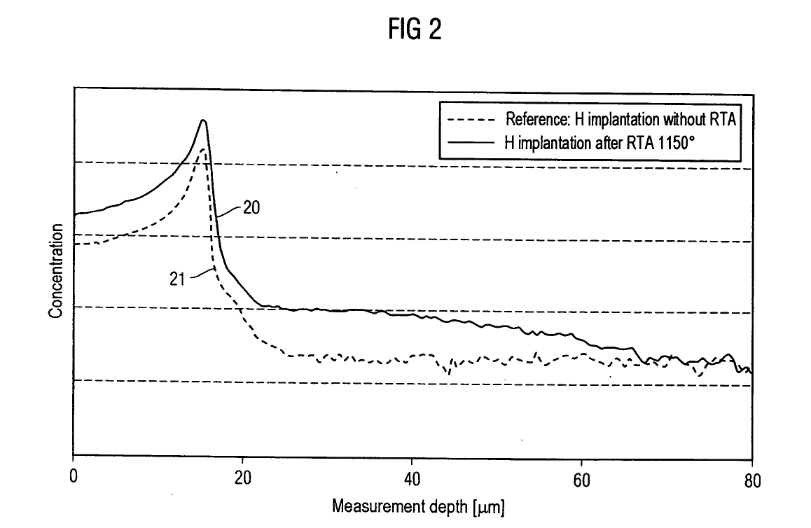

A representation of an experimentally determined doping profile that was produced by means of the method described above is illustrated schematically in FIG. 2. The doping profile having a small gradient that is present in the deeper region starting from approximately 20 μm was produced by the mechanism described above, the donors being formed from agglomerates of vacancies and hydrogen atoms. Without the nitriding RTA process, hydrogen atoms can admittedly also diffuse into the wafer depth, but the reactants required for donor formation, namely the vacancies, are absent. Moreover, the nitriding process step results in a significant increase in the incorporated concentration of hydrogen atom induced donors in the “end of range”, which can be “compensated for” by a lower implantation dose (that is to say that a lower implantation dose is necessary).

In the example shown in FIG. 2, the reference sample has a cumulative doping dose of 6.7·10¹¹l/cm², while the nitrided sample has a cumulative doping dose that is more than twice as high, of 1.6·10¹²/cm². This is particularly advantageous since only a few percent of the implanted hydrogen atoms ultimately act as donors and the implantation dose can be significantly reduced. Consequently, the costs for the implantation can be reduced.

Typical temperatures for the RTA step are temperatures of between 1000° C. and 1200° C. The duration of the RTA step may be a few seconds up to a few minutes depending on the desired penetration depth of the field stop zone in the semiconductor bodies. Typical doses for the proton irradiation which is suitable for producing a field stop zone lie in the range of from a few 10¹² up to a few 10¹⁵, preferably from a few 10¹³ up to a few 10¹⁴, protons/cm².

The heat treatment after the irradiation with protons should typically be carried out at temperatures of between 350° C. and 450° C. The time duration of this heat treatment typically lies between one and 4 hours.

One embodiment of the invention involves producing an n-doped field stop zone with a zone of high doping and a high gradient and a zone of lower doping and a low gradient by means of a nitriding RTA step, a subsequent proton irradiation and a concluding heat treatment.

The invention is explained in more detail below in exemplary embodiment with reference to the figures, in which:

FIG. 1 shows a cross-sectional illustration of a detail from an IGBT with a planar cell and a vertical construction together with an associated field distribution of the electric field in the off-state case,

FIG. 2 shows doping concentration profiles within a field stop layer which were measured with/without the use of an RTA process.

FIG. 2 illustrates measured doping concentration profiles within a field stop zone of a semiconductor component, the profile identified by reference numeral 20 corresponding to a fabrication method with an RTA process (fabrication method according to the invention), and the profile identified by reference numeral 21 corresponding to a fabrication method without an RTA process (conventional fabrication method) . In this case, “measurement depth” is to be understood to be the distance perpendicular to the rear side semiconductor body surface in the direction of the front side of the semiconductor component.

It can clearly be seen that with the use of an RTA process in a nitriding atmosphere prior to the proton irradiation process of the semiconductor body, a more intense doping results across the entire field stop zone. The RTA process in a nitriding atmosphere thus effects a “global” raising of the doping concentration. This means that, with the doping concentration remaining the same, an irradiation process having a lower irradiation dose can be used, which in turn reduces the fabrication costs for the field stop zone. The lower doping concentration resulting from the irradiation process having a lower irradiation dose is accordingly compensated for by the RTA process in a nitriding atmosphere, which raises the doping concentration.

The doping concentration profiles 20, 21 shown in FIG. 2 were preceded by a heat treatment of 400° C. in an inert atmosphere with a nitriding RTA step at 1150° C. and, respectively, without a nitriding RTA step.

What is claimed is:

1. A method for fabricating a field stop zone in a semiconductor body of a semiconductor component, the method comprising:
subjecting the semiconductor body to a rapid thermal annealing (RTA) process in a nitriding atmosphere;
irradiating the semiconductor body with protons after the semiconductor body is subjected to the RTA process; and
subjecting the irradiated semiconductor body to a heat treatment process.

2. The method of claim 1 wherein the temperature of the RTA process is between about 1000° C. and 1200° C.

3. The method of claim 1 wherein the duration of the RTA process is a plurality of seconds, but less than a plurality of hours.

4. The method of claim 1 wherein the duration of the RTA process is a plurality of hours.

5. The method of claim 1 wherein the doses of the protons during the step of irradiating are a plurality of 10¹² to 10¹⁵ protons/cm².

6. The method of claim 5 wherein the doses of the protons during the step of irradiating are a plurality of 10¹³ to 10¹⁴ protons/cm².

7. The method of claim 1 wherein the temperature of the heat treatment process is 350° C. to 450° C.

8. The method of claim 1 wherein the duration of the heat treatment process between one and four hours.

9. The method of claim 1 wherein an IGBT or a diode is fabricated by means of the method.

10. A method of fabricating a semiconductor component, the semiconductor component including a semiconductor body with a field stop zone, the method comprising:
a) subjecting the semiconductor body to a rapid thermal annealing (RTA) process in a nitriding atmosphere prior to the deposition of a metal layer or passivation layer on the semiconductor body;
b) irradiating a first side of the semiconductor body with protons after the semiconductor body is subjected to the RTA process, wherein the field stop zone is produced in the first side of the semiconductor body; and
c) subjecting the irradiated semiconductor body to a heat treatment process.

11. The method of claim 10 wherein the semiconductor component is an IGBT.

12. The method of claim 10 wherein the temperature of the RTA process is between about 1000° C. and 1200° C.

13. The method of claim 10 wherein the duration of the RTA process is a plurality of seconds, but less than a plurality of hours.

14. The method of claim 10 wherein the duration of the RTA process is a plurality of hours.

15. The method of claim 10 wherein the doses of the protons during the step of irradiating are a plurality of 10¹² to 10¹⁵ protons/cm².

16. The method of claim 15 wherein the doses of the protons during the step of irradiating are a plurality of 10¹³ to 10¹⁴ protons/cm².

17. The method of claim 10 wherein the temperature of the heat treatment process is 350° C. to 450° C.

18. The method of claim 10 wherein the duration of the heat treatment process between one and four hours.
